(19) United States
(12) Patent Application Publication
(10) Pub. No.: US 2026/0303037 A1
(43) Pub. Date: Oct. 1, 2026

(54) SYSTEM AND METHOD FOR ADAPTIVE POWER AMPLIFIER PROTECTION

(71) Applicant: QUALCOMM INCORPORATED, SAN DIEGO, CA (US)

(72) Inventors: Kai ZHAN, Escondido, CA (US); Bon-Hyun KU, San Diego, CA (US); Chuan WANG, San Diego, CA (US); Damin CAO, San Diego, CA (US); Rajagopalan RANGARAJAN, San Diego, CA (US); Kevin Hsi-Huai WANG, San Diego, CA (US)

(21) Appl. No.: 19/091,155

(22) Filed: Mar. 26, 2025

(51) Int. Cl. H03F 1/52; H03F 3/24; H03F 3/45

(52) U.S. Cl. CPC H03F 1/523; H03F 3/245; H03F 3/45179; H03F 2200/165; H03F 2200/171; H03F 2200/465

(57) ABSTRACT

A power amplifier (PA) protection circuit including a power detector circuit (DDET) configured to detect a power output of a power amplifier (PA), the PA including a cascode transistor, a static cascode bias circuit configured to selectively bias the PA cascode transistor, and a dynamic cascode bias circuit configured to selectively bias the PA cascode transistor responsive to the detected power output of the power amplifier (PA).

### FIELD

The present disclosure relates generally to electronics, and more specifically to a power amplifier protection system and method.

### BACKGROUND

Wireless communication devices and technologies are becoming ever more prevalent, as are communication devices that operate at millimeter-wave (mmW) and sub-terahertz (subTHz) frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications generally communicates using millimeter wave (mmW) frequency signals and sub-THz frequencies.

Transceivers used in some 5G communication systems generally use what is referred to as beamforming in which transmit signals are transmitted by a phased-array of antennas and receive signals are received by the array of antennas. Each antenna in the array may be associated with one or more amplifiers and one or more phase shifters. The phase shifters alter the phase of the transmit and receive signals so that the array may perform beamforming. Each power amplifier in the array may be responsible for transmitting a signal of a particular phase.

Reliability and aging of each power amplifier (PA) are critical parameters. PA lifetime reliability targets are critical metrics, and a given lifetime target typically sets an allowed voltage stress across the gate oxides of the transistors that form the PA. In particular, the voltage stress across the gate-drain oxide of the transistors should be maintained within certain values in order to meet the PA lifetime target. This is especially true for a cascode device in what is referred to as a “two-stack” PA or “multiple-stack” PA because the voltage stress across the gate-drain oxide is particularly sensitive to antenna impedance variations.

Therefore, it is desirable to have a power amplifier protection system and method that overcomes these and other drawbacks.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a power amplifier (PA) protection circuit including a power detector circuit (DDET) configured to detect a power output of a power amplifier (PA), the PA including a cascode transistor, a static cascode bias circuit configured to selectively bias the PA cascode transistor, and a dynamic cascode bias circuit configured to selectively bias the PA cascode transistor responsive to the detected power output of the power amplifier (PA).

Another aspect of the disclosure provides a method for protecting a power amplifier including biasing a cascode transistor of a power amplifier (PA) using a static cascode bias signal, determining whether a power output of a power amplifier exceeds a threshold more than a pre-determined number of times, and if the power output of the power amplifier exceeds the threshold more than the pre-determined number of times, biasing the cascode transistor of the power amplifier (PA) using an adaptive cascode bias signal.

Another aspect of the disclosure provides an adaptive bias circuit including a summing amplifier configured to receive an output of a drain voltage detector and generate an adaptive cascode bias signal, and a logic configured to receive an alarm signal and an enable signal, the logic configured to apply the adaptive cascode bias signal to a power amplifier (PA) responsive to the alarm signal and the enable signal.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a block diagram of a power amplifier system.

FIG. 4 is a block diagram of a circuit showing an exemplary phased array system.

FIG. 5 is a diagram showing a system for power amplifier protection in accordance with an exemplary embodiment of the disclosure.

FIG. 6 is a diagram showing an alternative embodiment of the system for power amplifier protection of FIG. 5.

FIG. 7 is a diagram showing another alternative embodiment of the system for power amplifier protection of FIG. 5.

FIG. 8 is a graphical illustration showing an example of the effect of the operation of the system for power amplifier protection of FIG. 5.

FIG. 9 is a block diagram of a power amplifier system.

FIG. 10 is a block diagram of a power amplifier system.

FIG. 11 is a flow chart describing an example of the operation of a method for adaptive power amplifier protection.

FIG. 12 is a functional block diagram of an apparatus for adaptive power amplifier protection.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, power amplifier (PA) reliability protection circuit attempts to protect the PA when the voltage stress across gate-drain oxide becomes high, such as due to variations in the antenna impedance. In some configurations, a conventional PA reliability protector circuit uses a drain-detector (DDET) to detect the voltage swing at the PA drain, a comparator to compare the detected voltage swing with a pre-defined threshold voltage, a counter that counts the occurrences of the threshold being exceeded and provides an alarm signal if certain pre-defined criterion are met. When an alarm signal is detected, the system will perform maximum transmit power level (MTPL) reduction by lowering RF input power level to protect the PA. Some such systems have drawbacks that include, for example, PA performance degradation when the PA output power is reduced, inability to distinguish between power amplifiers in a phased-array, resulting in all PAs in a phased array being subject to power reduction regardless of which PA in the array may be experience impedance variation, and inability to provide for a range of possible antenna impedances (VSWR2:1, VSWR4:1, VSWR10:1 for example), whereby excessive margin is preserved, which results in excessive/unnecessary PA performance degradation for a certain range of antenna impedances.

In accordance with an exemplary embodiment, a system and method for power amplifier protection uses a static bias circuit and an adaptive bias circuit to bias the cascode transistor devices in a power amplifier (PA).

In accordance with an exemplary embodiment, the adaptive part of the system and method for power amplifier protection is responsive to a detected voltage level at the drain of a cascode transistor of a multiple stack PA.

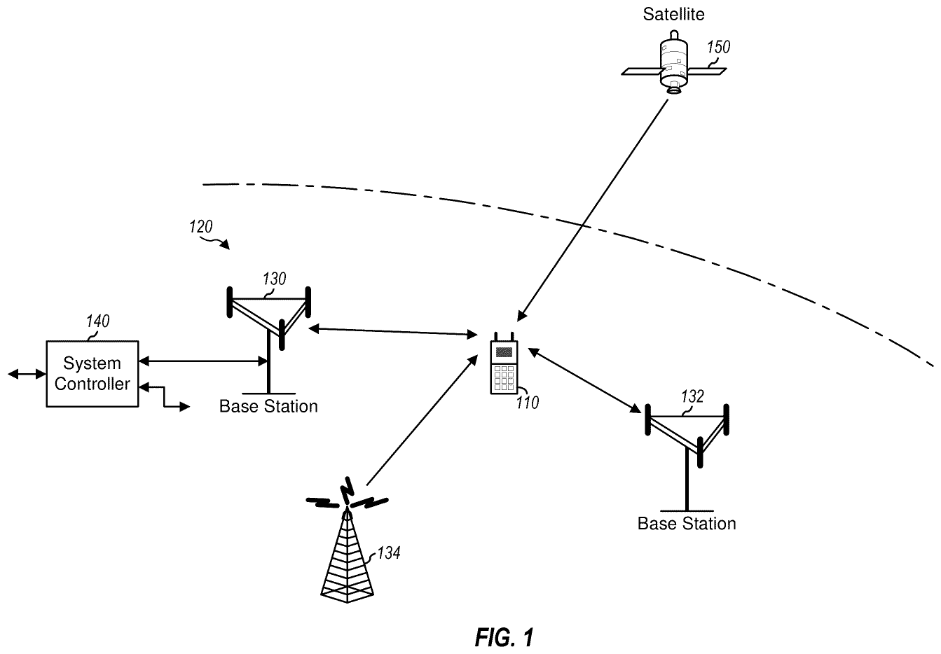

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS)), or a satellite that can receive signals from the wireless device 110, etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types—intra-band CA and inter-band CA. Intra-band CA refers to operation on multiple carriers within the same band. Inter-band CA refers to operation on multiple carriers in different bands.

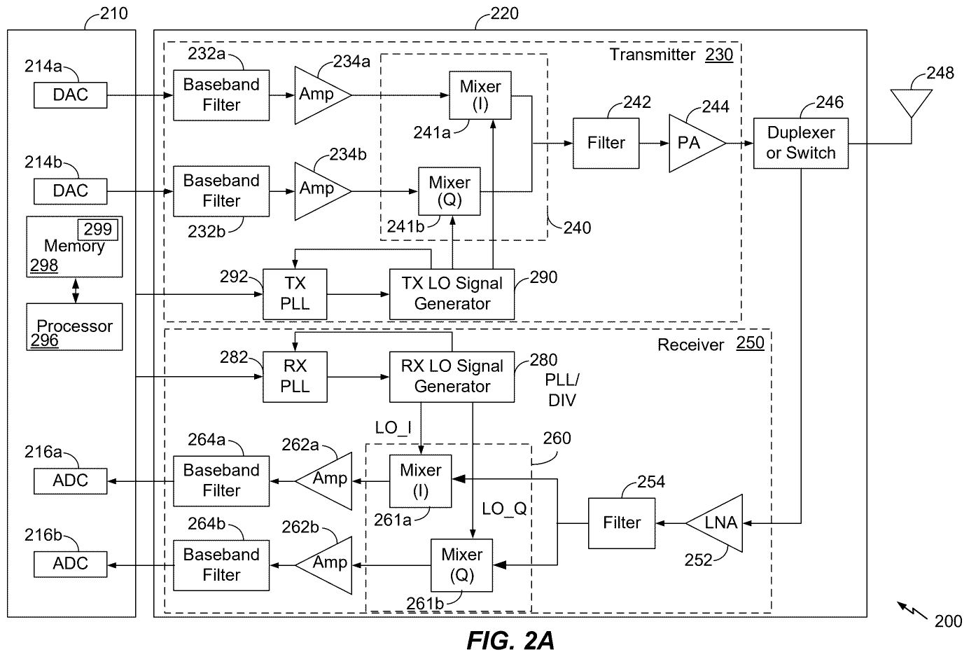

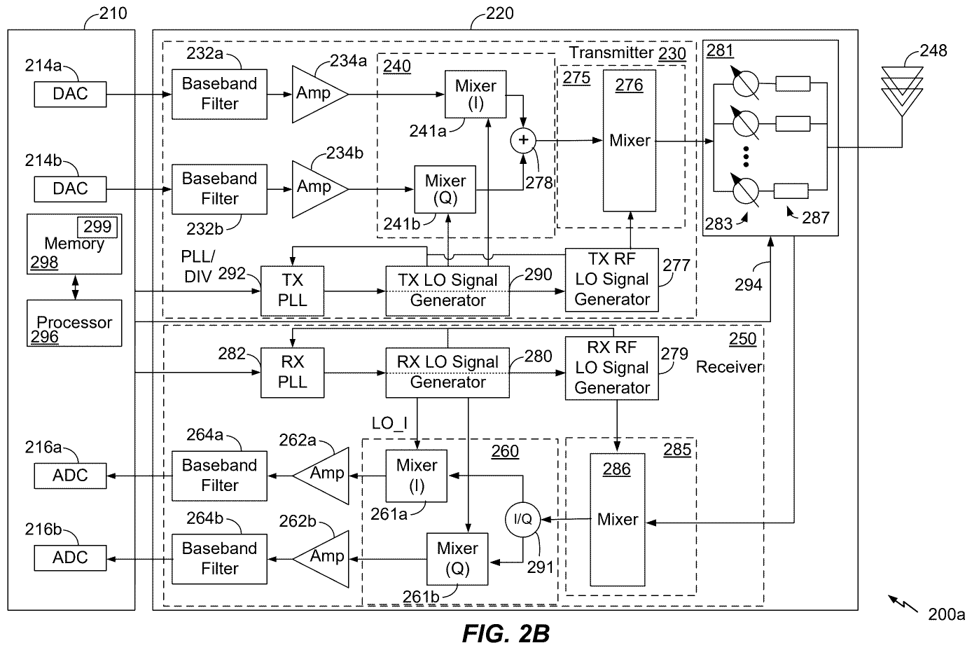

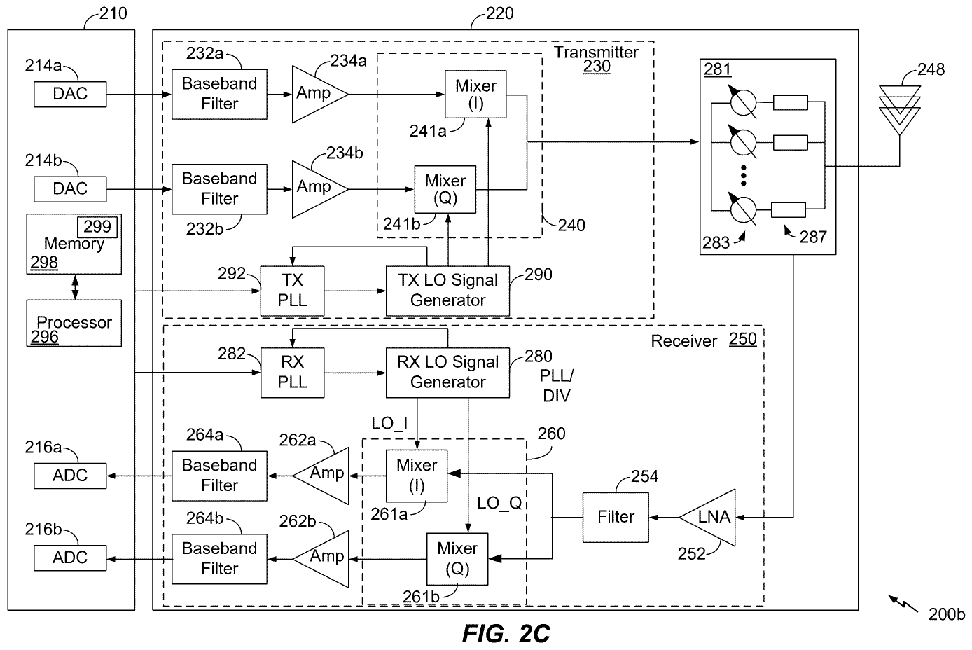

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the system and method for power amplifier protection described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may include a summing function 278 and may be configured to provide an IF signal to an upconverter 275. In an exemplary embodiment, the upconverter 275 may comprise upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, low noise amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The downconverter 260 includes an I/Q generation function 291. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

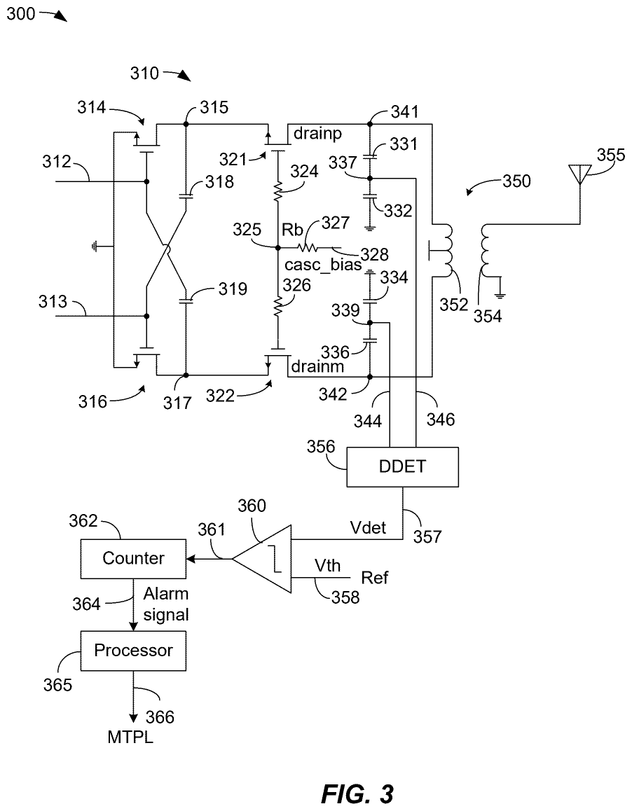

FIG. 3 is a block diagram 300 of a power amplifier system. The power amplifier system 300 may include a multiple-stack power amplifier 310, an electromagnetic element 350, an antenna 355, a drain voltage detector (DDET) 356, a comparator 360, a counter 362 and a processor 365. The power amplifier 310 may be included in one of the phased array elements 287 in some examples, and the antenna 355 may be an example of the antenna 248.

In an exemplary embodiment, the power amplifier 310 may comprise a two-stack cascode arrangement having gain transistors 314 and 316, and cascode transistors 321 and 322. In an exemplary embodiment, the gain transistors 314 and 316 may be configured to receive a differential input signal on connections 312 and 313 and provide output signals at their respective drain terminals at nodes 315 and 317. The node 315 is also connected to the source of the transistor 321 and the node 317 is connected to the source of the transistor 322. A gate of the transistor 314 is connected to the input connection 312 and the gate of the transistor 316 is connected to the input connection 313. The source of the transistor 314 and the source of the transistor 316 are connected to ground. A capacitance 319 is connected to the gate of the transistor 314 and the drain of the transistor 316, and a capacitance 318 is connected to the gate of the transistor 316 and the drain of the transistor 314.

A resistance 324 is connected between a node 325 and the gate of the transistor 321, and a resistance 326 is connected between the node 325 and the gate of the transistor 322. A resistance 327 is also connected to the node 325. A cascode bias signal, casc_bias, is applied to the other side of the resistance 327 over connection 328.

A drain of the transistor 321 is connected to a node 341 and the drain of the transistor 322 is connected to a node 342. A capacitance 336 is connected between the node 342 and a node 339, and a capacitance 334 is connected between the node 339 and system ground. A capacitance 331 is connected between the node 341 and a node 337, and a capacitance 332 is connected between the node 337 and system ground.

The node 341 and the node 342 are connected to sides of a primary element 352 of the electromagnetic element 350. A secondary side 354 of the electromagnetic element 350 is connected to the antenna 355. The connections described herein may be direct or indirect.

The DDET 356 is connected to the node 337 over connection 346 and is connected to the node 339 over connection 344. The DDET 356 is a drain voltage detector that detects the voltage at the drain of the transistor 321 at the node 337 and the drain of the transistor 322 at the node 339. The output of the DDET 356 is a drain voltage, Vdet on connection 357. The voltage, Vdet, is a positive voltage and is proportional to the voltage swing at the drain of the transistors 321 and 322 of the PA circuit 310.

The Vdet signal on connection 357 is provided to the comparator 360. A threshold voltage, Vth, is provided to the comparator 360 over connection 358 as a reference. The comparator 360 compares the Vdet signal on connection 357 against the threshold voltage, Vth, on connection 358 and provides an output signal on connection 361 when the voltage, Vdet exceeds the threshold Vth. The counter 362 counts the occurrences of the voltage signal on connection 361 exceeding the threshold voltage, Vth, and outputs an alarm signal on connection 364 when certain pre-defined criteria are satisfied. For example, the alarm signal on connection 364 may be present when a pre-defined number of occurrences of Vdet exceeding Vth is satisfied.

When the alarm signal on connection 364 is present, the processor 365 will perform a maximum transmit power level (MTPL) reduction process to lower the RF output power of the PA 310. The MTPL control signal may be provided on connection 366 and may be applied to the common input of the transmitter to reduce the input power, which essentially reduces the input power to the PA 310 at connections 312 and 313, and therefore reduces the power output of the PA 310. In a phased array system, all PAs in the phased array may derive their inputs from a common signal, and reduction of the input power may thus affect all PAs in the phased array. This arrangement therefore has certain drawbacks including, for example, an inability to respond to individual power amplifiers in a phased array system, an inability to respond to individual antenna impedance variations in a phased array system, and the general need to preserve excessive margin to cover a range of antenna impedances, resulting in excessive and/or unnecessary PA performance degradation for a certain range of antenna impedances that typically do not affect PA reliability.

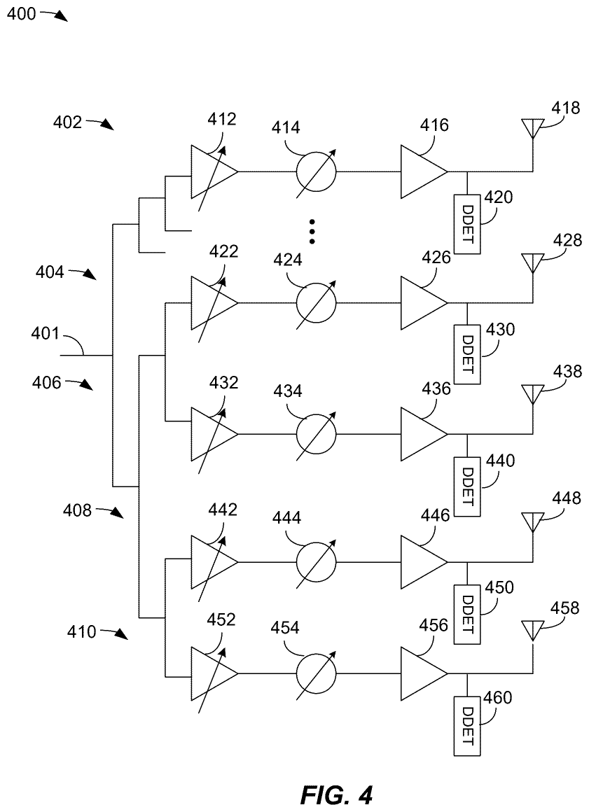

FIG. 4 is a block diagram 400 showing an exemplary phased array system. In an exemplary embodiment, the phased array system 400 may comprise a number of transmit chains, with exemplary transmit chains 402, 404, 406, 408 and 410 shown for example only. More or fewer transmit chains may be included in the phased array system 400. In an exemplary embodiment, the transmit chain 402 may comprise a driver amplifier 412, a phase shifter 414, a power amplifier 416, an antenna 418, and a DDET 420. Similarly, the transmit chain 404 may comprise a driver amplifier 422, a phase shifter 424, a power amplifier 426 an antenna 428, and a DDET 430; the transmit chain 406 may comprise a driver amplifier 432, a phase shifter 434, a power amplifier 436 an antenna 438, and a DDET 440; the transmit chain 408 may comprise a driver amplifier 442, a phase shifter 444, a power amplifier 446 an antenna 448, and a DDET 450; and the transmit chain 410 may comprise a driver amplifier 452, a phase shifter 454, a power amplifier 456 an antenna 458, and a DDET 460. The phased array system 400 (with the exception of the antennas 418, 428, 438, 448, 458) may be an example of elements included in the phase shift circuitry 281. Each of the power amplifiers 416, 426, 436, 446, 456 and the DDETs 420, 430, 440, 450, 460 may be configured as described with respect to the power amplifier 310 and the DDET 356, respectively.

In such a phased array system 400, each of the DDETs 420, 430, 440, 450 and 460 are fabricated to detect the voltage swing at the corresponding interface responding to impedance variations in respective antennas 418, 428, 438, 448 and 458. Each of the DDETs are followed by respective comparators and counters (as described with respect to FIG. 3, but not shown in FIG. 4). When the PA reliability protector of FIG. 3 is implemented in a phased array system 400, as long as one alarm signal is triggered from one transmit chain, the processor applies MTPL reduction to the common input on connection 401, which affects all transmit chains.

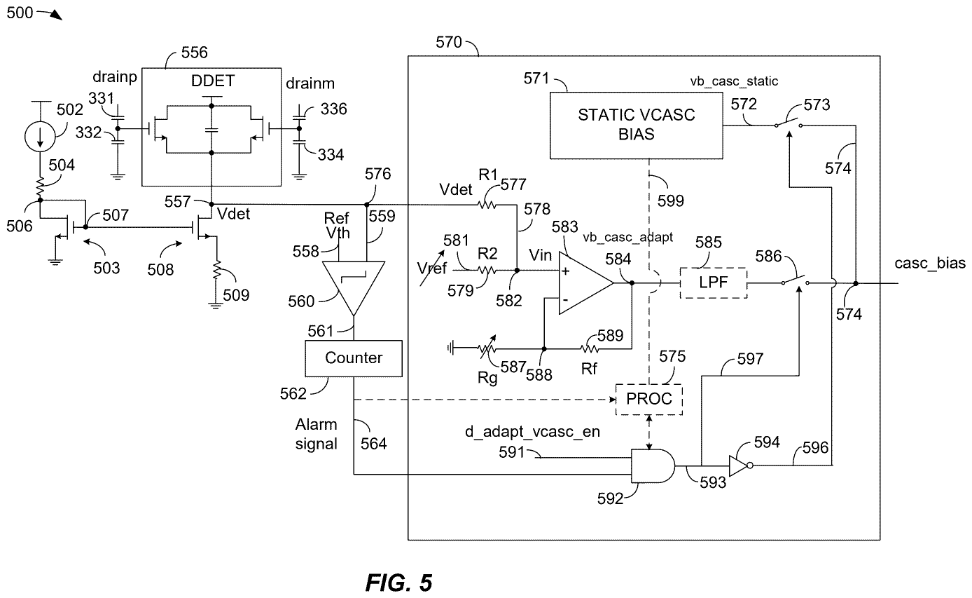

FIG. 5 is a diagram 500 showing a system for power amplifier protection in accordance with an exemplary embodiment of the disclosure. Elements in FIG. 5 that are similar to elements in FIG. 3 are numbered following the convention where an element in FIG. 5 labeled 5XX is similar to an element in FIG. 3 labeled 3XX.

In an exemplary embodiment, a DDET 556 provides a voltage, Vdet, on node 557. A transistor 508 has a drain connected to the node 557 and a source connected to system ground through a resistor 509. A gate of the transistor 508 is connected to a gate of a transistor 503. A current source 502 is connected through a resistance 504 to the drain of the transistor 503 at a node 506. The drain and gate of the transistor 503 are connected together and a source of the transistor 503 is connected to system ground. The circuit illustrated as implementing the DDET 556 is only an example, and it will be understood that other DDET circuits may be implemented.

In an exemplary embodiment, the node 557 is connected to an input of a comparator 560 at a connection 559. A threshold voltage, Vth, is applied as a reference signal to the comparator 560 at a connection 558.

The comparator 560 compares the Vdet signal on connection 559 against the threshold voltage, Vth, on connection 558 and provides an output signal on connection 561 when the value of Vdet exceeds the value of Vth. The counter 562 counts the occurrences of the voltage signal on connection 561 exceeding the threshold voltage, Vth, and outputs an alarm signal on connection 564 when certain pre-defined criteria are satisfied, as described with regard to FIG. 3.

An adaptive power amplifier protection circuit 570 is also configured to receive the voltage, Vdet, from a node 576, and the alarm signal on connection 564. The MTPL reduction process illustrated in FIG. 3 and the amplifier protection circuit 570 may share a DDET 356/556, comparator 360/560, and/or counter 362/562, or one or more of these elements can be implemented as separate, respective circuits for the MTPL reduction process and the amplifier protection circuit 570. For example, the counter 362 may be used for the MTPL reduction process and a separate counter 562 may be used for the amplifier protection circuit 570. Further, the threshold voltage Vth and/or the pre-defined criteria to output the alarm signal may be the same for the MTPL reduction process and for use with the amplifier protection circuit 570, or the threshold voltage Vth and/or the pre-defined criteria to output the alarm signal may differ between the MTPL reduction process and use with the amplifier protection circuit 570. In some examples, both the MTPL reduction process and the amplifier protection circuit 570 are implemented. In other examples, the MTPL reduction process is omitted.

In an exemplary embodiment, the adaptive power amplifier protection circuit 570 includes a static vcasc bias circuit 571, a summing amplifier 583, a logic 592, an inverter 594, switches 573 and 586, an optional low pass filter (LPF) 585 and an optional processor 575.

The static cascode bias signal vb_casc_static on connection 572 provided by the static vcasc bias circuit 571 is controlled by digital bits that may be stored in a memory, such as the memory 298 of FIGS. 2A, 2B or 2C.

In an exemplary embodiment, the Vdet signal on node 576 is applied through a resistor 577 over connection 578 to the non-inverting input of the summing amplifier 583 at a node 582. In an exemplary embodiment, the summing amplifier 583, a resistance 577, a resistance 579, a resistance 587 and a resistance 589 may form a non-inverting summing amplifier. A variable reference voltage, Vref, is applied through the resistance 579 to the node 582. An inverting input of the summing amplifier 583 is connected to a node 588. A variable resistance 587 is connected between the node 588 and system ground. An output of the summing amplifier 583 is provided at the node 584. A resistance 589 is connected between the node 584 and the node 588, which provides the inverting input to the summing amplifier 583. An output of the summing amplifier 583 is also provided to the optional LPF 585 and then to the switch 586. The switch 586 selectively provides an output over connection 574, which connects to the connection 328 in FIG. 3 (the casc_bias signal).

In an exemplary embodiment, the alarm signal on connection 564 is applied to one input of the logic 592. An enable signal, d_adapt_vcasc_en, is provided over connection 591 to the other input of the logic 592. The enable signal d_adapt_vcasc_en may be stored in a memory, such as the memory 298 of FIGS. 2A, 2B or 2C, and may be a 1-bit digital control having a value of either 0 or 1. In other examples, the logic 592 and the enable signal/connection 591 are omitted, and the alarm signal on connection 564 is directly connected to connection 593. In an exemplary embodiment, the d_adapt_vcasc_en signal functions to enable the adaptive power amplifier protection circuit 570. When the d_adapt_vcasc_en signal is logic 1, the signal on node 593 and connection 596 is determined by the state of the alarm signal on connection 564. The circuit selects the vb_casc_adapt signal on node 584 or the vb_casc_static signal on connection 572 based on whether the alarm signal is triggered. When the d_adapt_vcasc_en signal on connection 591 is logic 0, the node 593 is always logic 0 and the connection 596 is always logic 1 regardless of the state of the alarm signal, thereby selecting the vb_casc_static signal on connection 572 as the cascode bias signal, casc bias.

An output of the logic 592 is provided over connection 593 to the inverter 594, and over the connection 597 to the switch 586. In an exemplary embodiment, the logic circuit 592 is an AND logic gate. An output of the inverter 594 is provided over connection 596 to the switch 573. The connection 596 and the connection 597 carry control signals for respective switches 573 and 586. For example, if the signal on connection 596 is logic 0, the switch 573 is OFF, and connections 574 and 572 are disconnected. If the signal on connection 596 is logic 1, the switch 573 is ON, and the connections 574 and 572 are connected. Similar for the switch 586 and the control signal on connection 597. In an exemplary embodiment, the voltage, Vdet, on node 576 is positive and is proportional to the drain voltage swing of the cascode transistors 321 and 322 in the PA circuit 310. In an exemplary embodiment, the voltage, Vdet, is applied over connection 576 to the non-inverting input of the summing amplifier 583 through the resistance 577.

The summing amplifier 583 generates an adaptive cascode gate bias voltage, vb_casc_adapt, at the node 584, which is responsive to the voltage, Vdet. In an exemplary embodiment, the adaptive cascode gate bias voltage vb_casc_adapt=a*Vdet+b. The adaptive cascode gate bias voltage vb_casc_adapt is a positive voltage and is proportional to the drain voltage swing of the transistors 321 and 322 in the PA circuit 310. The coefficient “a” and the offset “b” can be adjusted by adjusting the values of the reference voltage, Vref, on connection 581 and by adjusting the value of the resistance 587 (Rg).

In an exemplary embodiment, the adaptive power amplifier protection circuit 570 minimizes reliability-performance tradeoffs. For example, the voltage stress across the gate-drain oxide of the cascode transistor devices 321 and 322 (FIG. 3) is referred to as Vdg, max and can be adaptively relaxed per power amplifier (for example, per power amplifier in FIG. 4, by implementing a respective adaptive power amplifier protection circuit 570 for each power amplifier in the phased array system 400) without the need for a universal MTPL reduction across all transmit chains in a phased array. For example, the voltage Vdg, max can be adaptively relaxed based on the corresponding antenna impedance without the need to know the actual antenna impedance. In an exemplary embodiment, a problematic PA can lower its voltage stress locally without negative affect on other non-problematic PAs in a phased array. Each power amplifier in the phased array may be associated with a respective static vcasc bias circuit 571, and/or multiple power amplifiers in the phased array may share a static vcasc bias circuit 571.

In an exemplary embodiment, the adaptive power amplifier protection circuit 570 is compatible with all techniques that utilize cascode gate bias for RF performance adjustment because the adaptive power amplifier protection circuit 570 only engages when a PA is experiencing excessive voltage stress that causes the alarm signal on connection 564 to be triggered.

In an exemplary embodiment, the adaptive power amplifier protection circuit 570 is compatible with other techniques of adjusting the RF voltage swing at the gate-drain of the cascode devices (for example the capacitance at the cascode gate).

In an exemplary embodiment, when the d_adapt_vcasc_en signal on connection 591 is at logic zero (0), the output of the logic 592 (e.g., the signal on connection 593) is at logic zero (0), the signal on connection 596 is at logic one (1), the switch 573 is on and switch 586 is off, the static gate bias signal vb_casc_static on connection 572 is passed through the switch 573, and then provides a signal on connection 574 that biases the cascode transistors 321 and 322 at the connection 328 (FIG. 3), regardless of whether the alarm signal is triggered and present on connection 564.

When the signal d_adapt_vcasc_en signal on connection 591 is logic high (1) and the alarm signal is present as logic high (1) on connection 564, the cascode transistors 321 and 322 in the PA circuit 310 (FIG. 3) are biased using the vb_casc_adapt signal on connection 584 because the output of the logic 592 is logic high (1) on connection 593 and a signal on connection 597 instructs the switch 586 to provide the output of the summing amplifier 583 (and LPF 585 if present) on connection 574, thus biasing the cascode transistors 321 and 322 over connection 328 (FIG. 3) using the vb_casc_adapt bias signal.

If the alarm signal is not present on connection 564, then the cascode transistors 321 and 322 are biased using the vb_casc_static signal on connection 572 and 574. It will be understood that the logic values and circuits described herein are only exemplary, and that other logic values and/or means for enabling an adaptive gate bias for the cascode transistors 321 and 322.

In an exemplary embodiment, the LPF 585 and the processor 575 are shown in dashed line and considered optional. In an exemplary embodiment, the optional LPF 585 performs a moving average of the signal vb_casc_adapt on connection 584 before it is applied as a cascode bias signal over connection 328. The optional LPF 585 helps to filter any sharp transitions in the vb_casc_adapt signal. Determining whether to include the LPF 585 may depend on the performance (error vector magnitude (EVM) and other parameters) in envelope simulations with different modulation waveforms, different number of carriers, etc.

The processor 575 is shown as optional because it may be located as shown in the adaptive power amplifier protection circuit 570, may be located elsewhere, such as in the data processor 210 of FIGS. 2A, 2B or 2C, or may be omitted altogether. When implemented, the processor 575 generates a control signal on connection 599 based on the alarm signal on connection 564 and on the d_adapt_vcasc_en signal on connection 591. As used herein, the term “static vcasc bias” means that the bias voltage provided by the static vcasc bias circuit 571 is constant over time. Thus, regardless of the output power that the power amplifier is transmitting at each moment and regardless of whether the power amplifier is experiencing high output swing, such events will not themselves affect the static vcasc bias. The static vcasc bias circuit 571 may be implemented to be digitally adjustable, meaning that the static bias signal, vb_casc_static, can be digitally adjusted to different values, for example 1V, 1.5V, etc. However, once the static bias is set to a value, it is static and not changing unless a further instruct instruction is received. In some examples, the processor 575 and the connection 599 are used only when the d_adapt_vcasc_en signal is logic 0, indicating that the static vcasc bias circuit 571 is always being selected to provide the vb_casc_static bias signal. For this optional control path, when the alarm signal on connection 564 is triggered and sent to the processor 575, the processor 575 determines whether the d_adapt_vcasc_en signal is logic 0 or logic 1, and determines the value of the existing vb_casc_static signal, and determines whether or not to adjust the vb_casc_static signal to a higher value. Whether the vb_casc_static signal is adjusted or not, the value of the vb_casc_static signal stays the same over time at the value to which it was set. In an exemplary embodiment, the optional control path 599 allows the processor 575 to control the value of vb_casc_static based on the state of the alarm signal on connection 564 when the d_adapt_vcasc_en signal on connection 591 is logic 0. The optional control path 599 may be relatively slow and implementation can be complex. Further, given the static nature of the static vcasc bias signal, it can be seen that the dynamic bias described herein (e.g., as provided through switch 586) can be quicker and more adaptive, and may provide better protection or similar protection while conserving power.

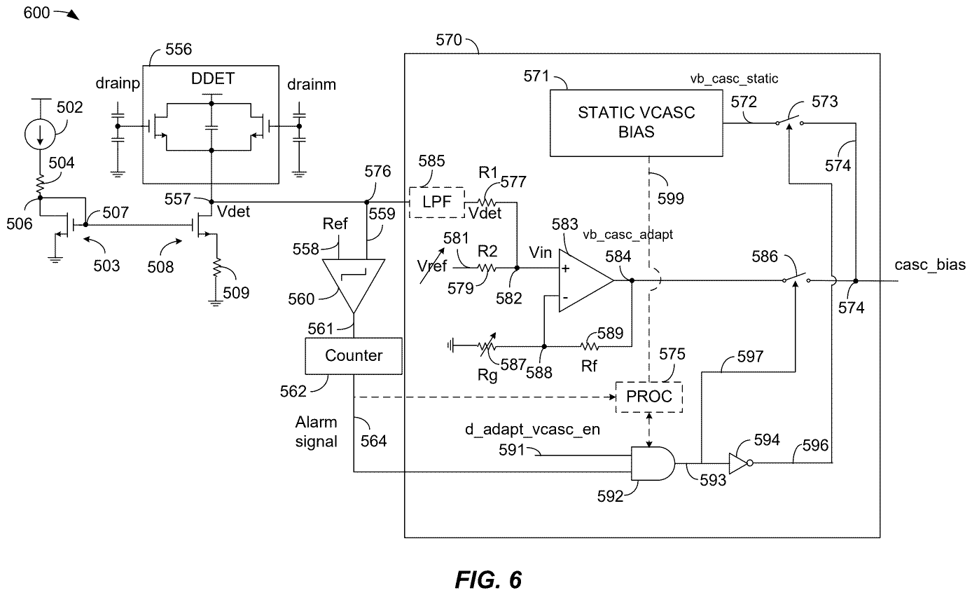

FIG. 6 is a diagram 600 showing an alternative embodiment of the system for power amplifier protection of FIG. 5. In FIG. 6, the optional LPF 585 is located at the input to the summing amplifier 583 and is configured to receive the Vdet signal on connection 576.

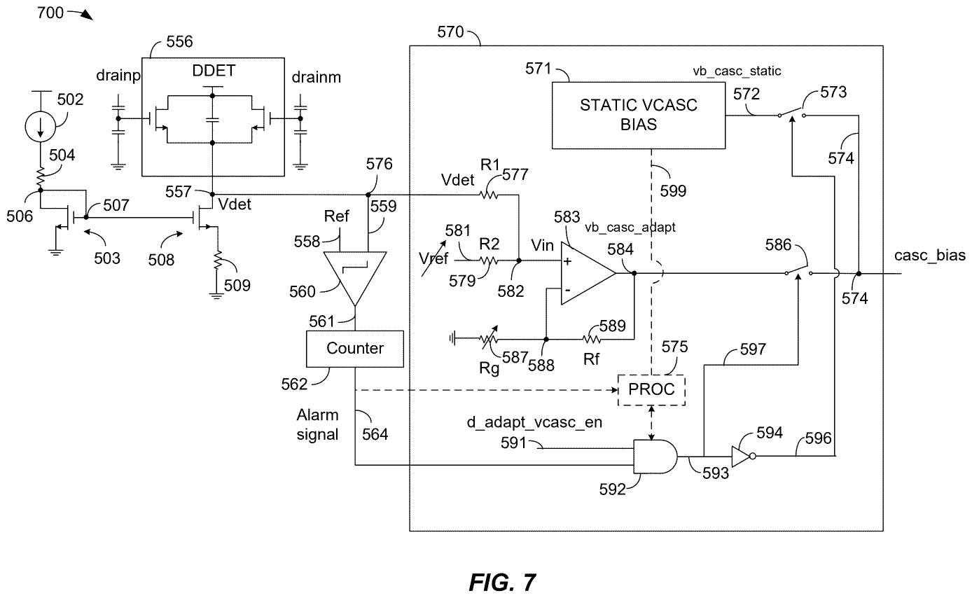

FIG. 7 is a diagram 700 showing another alternative embodiment of the system for power amplifier protection of FIG. 5. In FIG. 7, the optional LPF 585 is omitted.

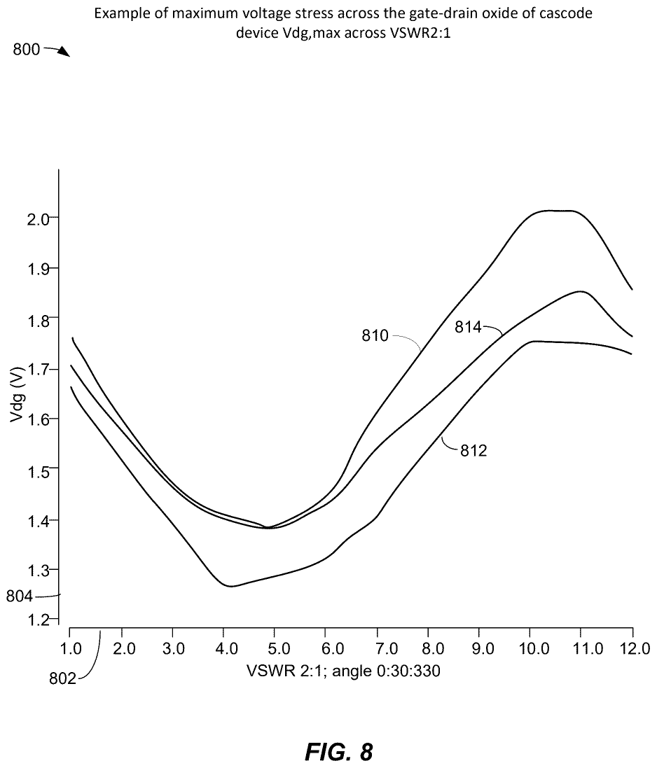

FIG. 8 is a graphical illustration 800 showing an example of the effect of the operation of the system for power amplifier protection of FIG. 5. The graph 800 includes a horizontal axis 802 showing VSWR and a vertical axis 804 showing gate-drain voltage, Vdg. The trace 810 shows an instance of Vdg, max across a VSWR of 2:1 with a conventional static vcasc bias circuit, such as the vcasc bias circuit 571 of FIG. 5.

The trace 812 shows an instance of Vdg, max across a VSWR of 2:1 with the adaptive power amplifier protection circuit 570 engaged.

The trace 814 shows another instance of Vdg, max across a VSWR of 2:1 with the adaptive power amplifier protection circuit 570 engaged. In an exemplary embodiment, the adaptive cascode bias signal vb_casc_adapt=a*Vdet+b. The coefficient “a” and the offset “b” can be adjusted. The two different traces 812 and 814 are two examples with different choices of coefficient “a” and offset “b”. As can be seen, the maximum voltage stress across the gate-drain oxide of cascode devices in the power amplifier is less when the adaptive power amplifier protection circuit 570 is engaged.

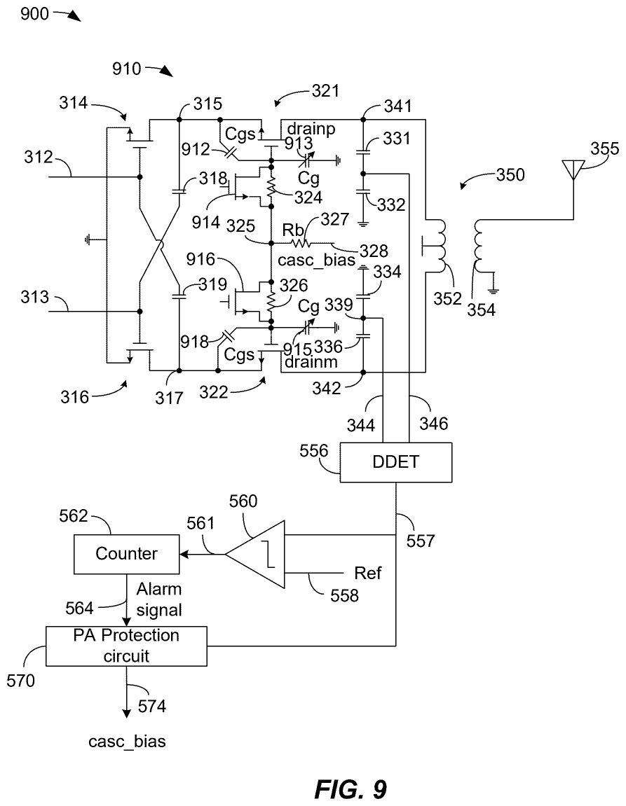

FIG. 9 is a block diagram 900 of a power amplifier system. The power amplifier system 900 may include an alternative exemplary embodiment of the multiple-stack power amplifier of FIG. 3. Elements in FIG. 9 that are identical to elements in FIG. 3 and FIG. 5 are identically numbered. In an exemplary embodiment, a multiple-stack power amplifier 910 may include a capacitance 912 (Cgs) across the gate and source of the transistor 321, and an adjustable capacitance 913 connected between the gate of the transistor 321 and system ground, and may include a capacitance 918 (Cgs) across the gate and source of the transistor 322 and an adjustable capacitance 915 connected between the gate of the transistor 322 and system ground. In an exemplary embodiment, the capacitance 912 (Cgs) and the capacitance 918 (Cgs) may be the intrinsic parasitic gate-source capacitance of the transistor 321 and the transistor 322 respectively. A switch 914 (SW1) may be connected across the resistance 324 and a switch 916 (SW1) may be connected across the resistance 326. The switch 914 and the switch 916, and the adjustable capacitance 913 and adjustable capacitance 915 may be controlled by a control signal from the data processor 210 (FIGS. 2A, 2B, 2C) or another controller.

In an exemplary embodiment, the arrangement shown in FIG. 9 is an alternative embodiment that uses a capacitive divider to sense a portion of RF voltage swing at the gate of the cascode transistors 321 and 322. It can work together (co-exist) with the adaptive PA protector circuit shown in FIGS. 5, 6 and 7. The node 325 is RF virtual ground. The resistor 324 and the resistor 326 may be relatively large to avoid pulling the gates of the transistors 321 and 322 to RF virtual ground. The switches 914 and 916 may be OFF to also avoid pulling the gates of the transistors 321 and 322 to RF virtual ground. The capacitance 912 and the capacitance 913 form a capacitive divider, whereby a portion of the RF voltage swing at node 315 will appear on the gate of the transistor 321. By adjusting the capacitance 913, the amplitude of the voltage swing at the gate of the transistor 321 can be adjusted. The voltage swing at the gate of the transistor 321 is in-phase with the voltage swing at node 315 (due to the capacitive divider), as well as in-phase with the voltage swing at the drain of the transistor 321. With the voltage swing at the gate and drain of the transistor 321 in-phase, the drain-gate voltage, Vdg (Vd-Vg) of the transistor 321 will be further reduced. This feature can be disabled by turning the switch 914 (SW1) to ON bypassing the resistance 324.

Similarly, the capacitance 918 and the capacitance 915 form a capacitive divider, whereby a portion of the RF voltage swing at node 317 will appear on the gate of the transistor 322. By adjusting the capacitance 915, the amplitude of the voltage swing at the gate of the transistor 322 can be adjusted. The voltage swing at the gate of the transistor 322 is in-phase with the voltage swing at node 317 (due to the capacitive divider), as well as in-phase with the voltage swing at the drain of the transistor 322. With the voltage swing at the gate and drain of the transistor 322 in-phase, the drain-gate voltage, Vdg (Vd-Vg) of the transistor 322 will be further reduced. This feature can be disabled by turning the switch 916 (SW1) to ON bypassing the resistance 326. The switches 914 and 916 can be controlled by a control signal from the data processor 210 (FIGS. 2A, 2B, 2C) or another controller.

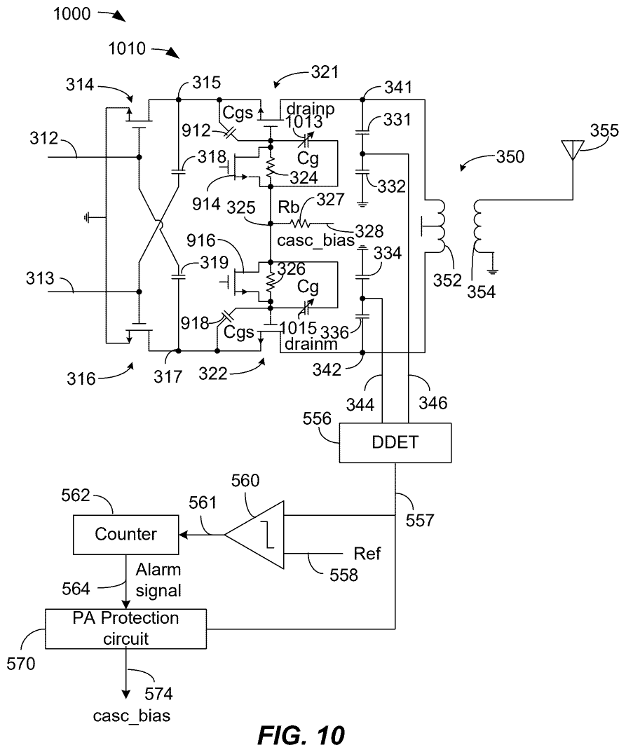

FIG. 10 is a block diagram 1000 of a power amplifier system. The power amplifier system 1000 may include an alternative exemplary embodiment of the multiple-stack power amplifier of FIG. 3 and FIG. 9. Elements in FIG. 10 that are identical to elements in FIG. 3, FIG. 5 and FIG. 9 are identically numbered. In an exemplary embodiment, a multiple-stack power amplifier 1010 may include an adjustable capacitance 1013 connected across the resistance 324 and connected to the gate of the transistor 321. The multiple-stack power amplifier 1010 may include an adjustable capacitance 1015 connected across the resistance 326 and connected to the gate of the transistor 322. The value of the adjustable capacitance 1013 and the value of the adjustable capacitance 1015 may be controlled by a control signal from the data processor 210 (FIGS. 2A, 2B, 2C) or another controller. In FIG. 10, the two gate capacitances 1013 and 1015 are connected between the gates of the transistors 321 and 322 and the RF virtual ground at node 325. Adjusting the values of the variable capacitances 1013 and 1015 can adjust the RF voltage swing at gates of the transistors 321 and 322, as described above in FIG. 9.

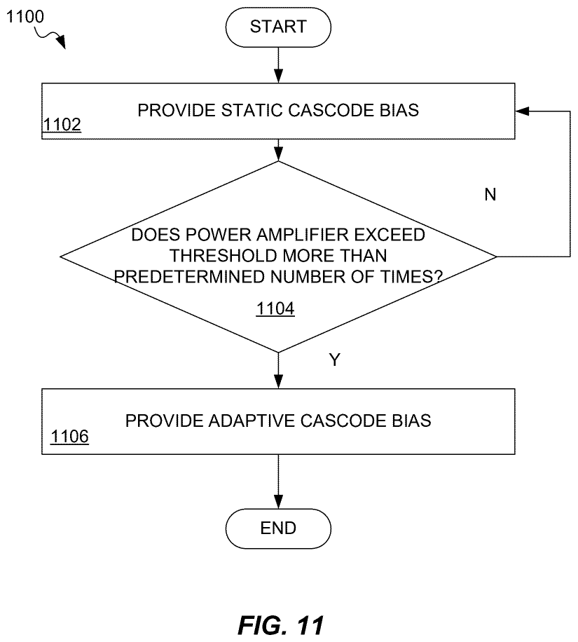

FIG. 11 is a flow chart 1100 describing an example of the operation of a method for adaptive power amplifier protection. The blocks in the method 1100 can be performed in or out of the order shown, and in some embodiments, can be performed at least in part in parallel.

In block 1102, a static cascode bias voltage is provided. For example, the static vcasc bias circuit 571 provides the vb_casc_static bias signal to the connection 328 to bias the cascode transistors 321 and 322 of FIG. 3.

In block 1104, it is determined whether an output of a power amplifier exceeds a threshold more than a predetermined number of times. For example, a threshold voltage, Vth, is provided to the comparator 560 over connection 558 as a reference. The comparator 560 compares the Vdet signal on connection 559 against the threshold voltage, Vth, on connection 558 and provides an output signal on connection 561 when the voltage, Vdet exceeds the threshold Vth. The counter 562 counts the occurrences of the voltage signal on connection 561 exceeding the threshold voltage, Vth, and outputs an alarm signal on connection 564 when a pre-defined number of occurrences of Vdet exceeding Vth is satisfied. If in block 1104, it is determined that an output of the power amplifier does not exceed the threshold more than a predetermined number of times, the process returns to block 1102. If in block 1104, it is determined that an output of the power amplifier exceeds the threshold more than a predetermined number of times, the process proceeds to block 1106.

In block 1106 the adaptive bias signal is applied to the cascode transistors of the power amplifier circuit 310 (or 910 or 1010). For example, the vb_casc_adapt signal on connection 584 is applied through the switch 586 to the connection 574 and then to the connection 328 to adaptively bias the cascode transistors 321 and 322 (FIG. 3).

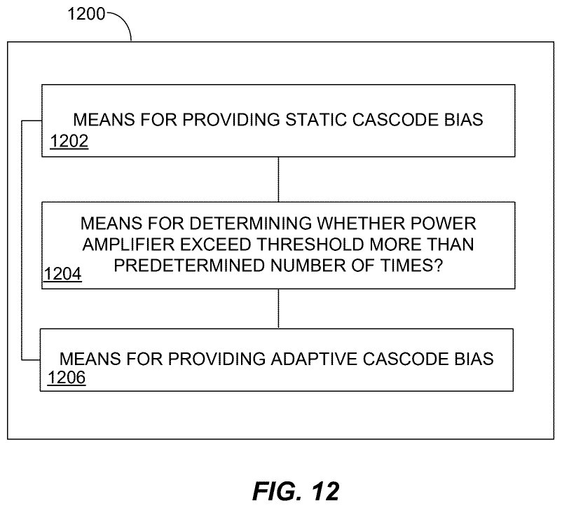

FIG. 12 is a functional block diagram of an apparatus 1200 for adaptive power amplifier protection. The apparatus 1200 comprises means 1202 for providing a static cascode bias voltage. In certain embodiments, the means 1202 for providing a static cascode bias voltage can be configured to perform one or more of the functions described in operation block 1102 of method 1100 (FIG. 11). In an exemplary embodiment, the means 1202 for providing a static cascode bias voltage may comprise the static vcasc bias circuit 571 configured to provide the vb_casc_static bias signal to the connection 328 to bias the cascode transistors 321 and 322 of FIG. 3.

The apparatus 1200 also comprises means 1204 for determining whether an output of a power amplifier exceeds a threshold more than a predetermined number of times. In certain embodiments, the means 1204 for determining an output of a power amplifier exceeds a threshold more than a predetermined number of times can be configured to perform one or more of the functions described in operation block 1104 of method 1100 (FIG. 11). In an exemplary embodiment, the means 1204 for determining whether an output of a power amplifier exceeds a threshold more than a predetermined number of times may comprise the comparator 560 configured to compare the Vdet signal on connection 559 against the threshold voltage, Vth, on connection 558 and provide an output signal on connection 561 when the voltage, Vdet exceeds the threshold Vth; and the counter 362 configured to count the occurrences of the voltage signal on connection 561 exceeding the threshold voltage, Vth, and output an alarm signal on connection 564 when a pre-defined number of occurrences of Vdet exceeding Vth is satisfied.

The apparatus 1200 also comprises means 1206 for applying the adaptive bias signal to the cascode transistors of the power amplifier circuit. In certain embodiments, the means 1206 for applying the adaptive bias signal to the cascode transistors of the power amplifier circuit can be configured to perform one or more of the functions described in operation block 1106 of method 1100 (FIG. 11). In an exemplary embodiment, the means 1206 for applying the adaptive bias signal to the cascode transistors of the power amplifier circuit may comprise components of FIGS. 5-7 configured to apply the vb_casc_adapt signal on connection 584 through the switch 586 to the connection 574 and then to the connection 328 to adaptively bias the cascode transistors 321 and 322 (FIG. 3).

Implementation examples are described in the following numbered clauses:

1. A power amplifier (PA) protection circuit, comprising: a power detector circuit (DDET) configured to detect a power output of a power amplifier (PA), the PA including a cascode transistor; a static cascode bias circuit configured to selectively bias the PA cascode transistor; and a dynamic cascode bias circuit configured to selectively bias the PA cascode transistor responsive to the detected power output of the power amplifier (PA).

2. The PA protection circuit of clause 1, wherein the dynamic cascode bias circuit further comprises: a summing amplifier configured to generate an adaptive cascode bias signal (Vb_casc_adapt) responsive to an output of the power detector circuit.

3. The PA protection circuit of any of clauses 1 through 2, wherein the PA is one of a plurality of PAs in a mmW phased array and the PA cascode transistor is individually biased by the dynamic cascode bias circuit.

4. The PA protection circuit of any of clauses 1 through 3, wherein the logic circuit is configured to receive an enable signal (d_adapt_vcasc_en) and an alarm signal from the counter.

5. The PA protection circuit of any of clauses 1 through 4, further comprising: a comparator connected to an output of the power detector circuit; a counter connected to an output of the comparator; and a logic circuit connected to an output of the counter, wherein an output of the logic circuit is configured to control whether the static cascode bias circuit biases the PA cascode transistor and whether the dynamic cascode bias circuit biases the PA cascode transistor

6. The PA protection circuit of clause 5, wherein the logic circuit selects the output of the comparator in the dynamic cascode bias circuit wherein the logic circuit is an AND gate having a first input comprising the enable signal (d_adapt_vcasc_en) and a second input comprising the alarm signal from the counter. to bias the PA cascode transistor when the enable signal (d_adapt_vcasc_en) and the alarm signal from the counter are logic high.

7. The PA protection circuit of any of clauses 2 through 6, further comprising a low pass filter (LPF) connected to an output of the summing amplifier.

8. The PA protection circuit of any of clauses 2 through 6, further comprising a low pass filter (LPF) connected to an input of the summing amplifier.

9. The PA protection circuit of clause 6, wherein the PA is differential and further comprises a second cascode transistor, and wherein an output of the dynamic cascode bias circuit is selectively connected to gates of the cascode transistor and the second cascode transistor.

10. A method for protecting a power amplifier, comprising: biasing a cascode transistor of a power amplifier (PA) using a static cascode bias signal; determining whether a power output of a power amplifier exceeds a threshold more than a pre-determined number of times; and if the power output of the power amplifier exceeds the threshold more than the pre-determined number of times, biasing the cascode transistor of the power amplifier (PA) using an adaptive cascode bias signal.

11. The method of clause 10, wherein the adaptive cascode bias signal is responsive to the power output of the power amplifier.

12. The method of any of clauses 10 through 11, wherein the PA is one of a plurality of PAs in a mmW phased array and the PA is individually biased by the adaptive cascode bias signal.

13. The method of any of clauses 10 through 12, wherein the adaptive cascode bias signal is responsive to an enable signal (d_adapt_vcasc_en) and an alarm signal representative of the threshold being exceeded.

14. The method of clause 13, wherein the adaptive cascode bias signal is applied when the enable signal (d_adapt_vcasc_en) and the alarm signal are logic high.

15. The method of clause 13, wherein the adaptive cascode bias signal is applied to a gate of the cascode transistor.

16. An adaptive bias circuit, comprising: a summing amplifier configured to receive an output of a drain voltage detector and generate an adaptive cascode bias signal; and a logic configured to receive an alarm signal and an enable signal, the logic configured to apply the adaptive cascode bias signal to a power amplifier (PA) responsive to the alarm signal and the enable signal.

17. The adaptive bias circuit of clause 16, further comprising a low pass filter (LPF) at an output of the summing circuit.

18. The adaptive bias circuit of clause 16, further comprising a low pass filter (LPF) at an input of the summing circuit.

19. The adaptive bias circuit of any of clauses 16 through 18, wherein the PA is one of a plurality of PAs in a mmW phased array and the PA is individually biased by the adaptive bias circuit.

20. The adaptive bias circuit of any of clauses 16 through 19, wherein the logic is an AND gate having a first input comprising the enable signal and a second input comprising the alarm signal.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A power amplifier (PA) protection circuit, comprising:
a power detector circuit (DDET) configured to detect a power output of a power amplifier (PA), the PA including a cascode transistor;
a static cascode bias circuit configured to selectively bias the PA cascode transistor; and
a dynamic cascode bias circuit configured to selectively bias the PA cascode transistor responsive to the detected power output of the power amplifier (PA).

2. The PA protection circuit of claim 1, wherein the dynamic cascode bias circuit further comprises:
a summing amplifier configured to generate an adaptive cascode bias signal (Vb_casc_adapt) responsive to an output of the power detector circuit.

3. The PA protection circuit of claim 1, wherein the PA is one of a plurality of PAs in a mmW phased array and the PA cascode transistor is individually biased by the dynamic cascode bias circuit.

4. The PA protection circuit of claim 1, further comprising:
a comparator connected to an output of the power detector circuit;
a counter connected to an output of the comparator; and
a logic circuit connected to an output of the counter, wherein an output of the logic circuit is configured to control whether the static cascode bias circuit biases the PA cascode transistor and whether the dynamic cascode bias circuit biases the PA cascode transistor.

5. The PA protection circuit of claim 4, wherein the logic circuit is configured to receive an enable signal (d_adapt_vcasc_en) and an alarm signal from the counter.

6. The PA protection circuit of claim 4, wherein the logic circuit selects the output of the comparator in the dynamic cascode bias circuit, wherein the logic circuit is an AND gate having a first input comprising the enable signal (d_adapt_vcasc_en) and a second input comprising the alarm signal from the counter to bias the PA cascode transistor when the enable signal (d_adapt_vcasc_en) and the alarm signal from the counter are logic high.

7. The PA protection circuit of claim 2, further comprising a low pass filter (LPF) connected to an output of the summing amplifier.

8. The PA protection circuit of claim 2, further comprising a low pass filter (LPF) connected to an input of the summing amplifier.

9. The PA protection circuit of claim 6, wherein the PA is differential and further comprises a second cascode transistor, and wherein an output of the dynamic cascode bias circuit is selectively connected to gates of the cascode transistor and the second cascode transistor.

10. A method for protecting a power amplifier, comprising:
biasing a cascode transistor of a power amplifier (PA) using a static cascode bias signal;
determining whether a power output of a power amplifier exceeds a threshold more than a pre-determined number of times; and
if the power output of the power amplifier exceeds the threshold more than the pre-determined number of times, biasing the cascode transistor of the power amplifier (PA) using an adaptive cascode bias signal.

11. The method of claim 10, wherein the adaptive cascode bias signal is responsive to the power output of the power amplifier.

12. The method of claim 10, wherein the PA is one of a plurality of PAs in a mmW phased array and the PA is individually biased by the adaptive cascode bias signal.

13. The method of claim 10, wherein the adaptive cascode bias signal is responsive to an enable signal (d_adapt_vcasc_en) and an alarm signal representative of the threshold being exceeded.

14. The method of claim 13, wherein the adaptive cascode bias signal is applied when the enable signal (d_adapt_vcasc_en) and the alarm signal are logic high.

15. The method of claim 13, wherein the adaptive cascode bias signal is applied to a gate of the cascode transistor.

16. An adaptive bias circuit, comprising:
a summing amplifier configured to receive an output of a drain voltage detector and generate an adaptive cascode bias signal; and
a logic configured to receive an alarm signal and an enable signal, the logic configured to apply the adaptive cascode bias signal to a power amplifier (PA) responsive to the alarm signal and the enable signal.

17. The adaptive bias circuit of claim 16, further comprising a low pass filter (LPF) at an output of the summing amplifier.

18. The adaptive bias circuit of claim 16, further comprising a low pass filter (LPF) at an input of the summing amplifier.

19. The adaptive bias circuit of claim 16, wherein the PA is one of a plurality of PAs in a mmW phased array and the PA is individually biased by the adaptive bias circuit.

20. The adaptive bias circuit of claim 16, wherein the logic is an AND gate having a first input comprising the enable signal and a second input comprising the alarm signal.
